(19) United States
(12) Patent Application Publication
(10) Pub. No.: US 2009/0014787 A1
(43) Pub. Date: Jan. 15, 2009

(54) Multi-Layer Semiconductor Structure and Manufacturing Method Thereof

(75) Inventor: Ting Sing Wang, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/969,702

(22) Filed: Jan. 4, 2008

(30) Foreign Application Priority Data
Jul. 11, 2007 (TW) 096125159

(51) Int. Cl. H01L 29/78; H01L 21/336

(52) U.S. Cl. 257/331; 438/270; 257/E29.262; 257/E21.41

(57) ABSTRACT

A power MOSFET structure comprises at least one first gate in the cell area and at least one second gate at the peripheral that are both in a semiconductor substrate. The first and second gates are electrically connected, and the second gate is connected to a contact so as to electrically connect to a bond pad for transmitting gate control signals. The semiconductor substrate comprises a first semiconductor layer, a second semiconductor layer and a third semiconductor layer in downward sequence. The first and third semiconductor layers are of a first conductive type, e.g., n-type, and the second semiconductor layer is of a second conductive type, e.g., p-type. The first and third semiconductor layers serve as the source and the drain, respectively.

### BACKGROUND OF THE INVENTION

(A) Field of the Invention

The present invention relates to a metal oxide semiconductor field effect transistor (MOSFET) structure and the manufacturing method thereof, and more specifically, to a power MOSFET structure and the manufacturing method thereof.

(B) Description of the Related Art

Power MOSFETs become the main stream of high power devices and the leading product on the market. Demands for smaller sizes and high functionalities in electronic apparatuses such as computers have resulted in the development of power MOSFET, and related technologies are still growing. With the support of the huge market for computers, IC engineers used monolithic technology and made a breakthrough for high power MOSFET devices. Especially the performance of high power MOS devices with low voltage endurance are significantly increased with the increase in integrity of MOSFETs. High power MOSFETs are suitable for use in driver ICs and protection circuit ICs.

FIG. 1 shows a known power MOSFET structure 10. A substrate 11 comprises an n⁻-type semiconductor layer 13 formed by an epi process on an n⁺-type semiconductor layer 12, and p⁻-type semiconductor layer 14 and an n⁺-type semiconductor layer 15. The trenches on the left side are filled with polysilicon to form gates 16 and 17, and the n⁺-type semiconductor layer 15 and the n⁻-type semiconductor layer 13 act as the source and the drain, respectively. A gate 18 on the right side is formed on the surface of the substrate 11 at the peripheral of the die, and is connected to a bonding pad through contact 19 and related metal interconnection for transmitting signals to control the gates 16, 17 and 18.

Because the gate 18 is formed on the surface of the substrate 11, the gate 18 needs to be defined by a photo mask, and the location of the gate 18 before the gate 18 is formed, i.e., an isolation area without devices, needs to be defined by a photo mask. Therefore, the manufacturing process becomes complicated and the cost of photo masks cannot be reduced effectively.

### SUMMARY OF THE INVENTION

The present invention provides a power MOSFET structure and manufacturing method thereof to reduce the number of photo masks, so as to simplify processes and reduce manufacturing costs.

In accordance with a power MOSFET structure of the present invention, a first gate in cell area of a die and a second gate at the peripheral are formed in the semiconductor substrate. The first and second gates are electrically connected, and the second gate is connected to a contact that is connected to a bonding pad to transmit gate control signal. The semiconductor substrate comprises a first semiconductor layer, a second semiconductor layer and a third semiconductor layer. The first and third semiconductor layers is of a first conductive type, e.g., n-type, and the second semiconductor layer is of a second conductive type, e.g., p-type. The first and third semiconductor layers act respectively as the source and the drain of the power MOSFET structure.

In an embodiment for manufacturing the power MOSFET structure, a first trench and a second trench are formed in a semiconductor substrate, and the first and second trenches are filled with a conductive layer such as doped polysilicon to form the first and second gates. The first and second gates are electrically connected. A dielectric layer is formed sequentially on the first gate, the second gate and the semiconductor substrate, and a contact penetrating the dielectric layer to the second gate is formed. The contact is electrically connected to a first bonding pad to transmit gate control signals.

In comparison with the traditional power MOSFET structure where gates at the peripheral of the die are formed on the substrate, the gates are formed in the semiconductor substrate at the same time in the present invention. Therefore, it is unnecessary to make a photo mask defining the gate connecting the contact, and the mask defining the isolation area for formation of the gate connecting the contact is also not needed. Moreover, another contact photo mask is currently used in the non-n+ regions of p− substrate at n+ peripheral to etch and remove the n+ regions, and a p+ guard ring is generated by p+ ion implantation to stabilize the voltage of p− substrate. In other words, three photo masks in total can be spared.

### BRIEF DESCRIPTION OF THE DRAWINGS

FIG. 1 shows a known power MOSFET structure; and

FIGS. 2 through 12 show a process for making a power MOSFET structure in accordance with the present invention.

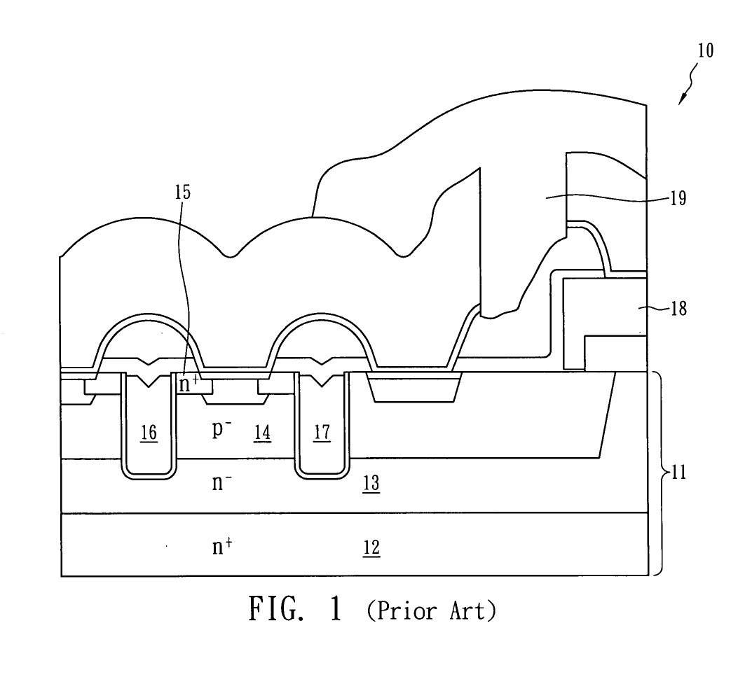

### DETAILED DESCRIPTION OF THE INVENTION

The power MOSFET structure and the manufacturing method thereof of the present invention are clearly explained with reference to the appended drawings.

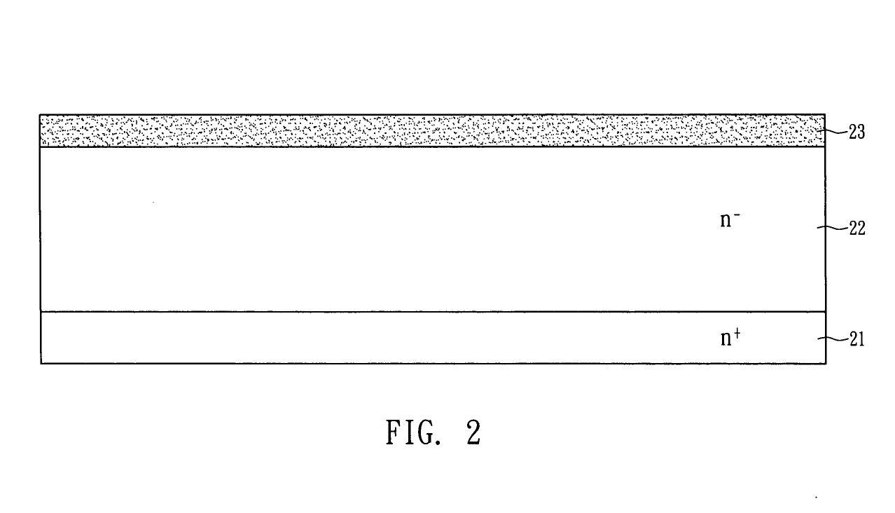

FIGS. 2 through 12 shows an embodiment of making a power MOSFET structure in accordance with the present invention.

In FIG. 2, an n⁻-type semiconductor layer 22 is formed on an n⁺-type semiconductor substrate 21. The thickness of the n⁻-type semiconductor layer 22 is between 4 and 4.5 μm. Then, an oxidation process at 1000° C. is performed to form an oxide layer 23 of around 6000 angstroms.

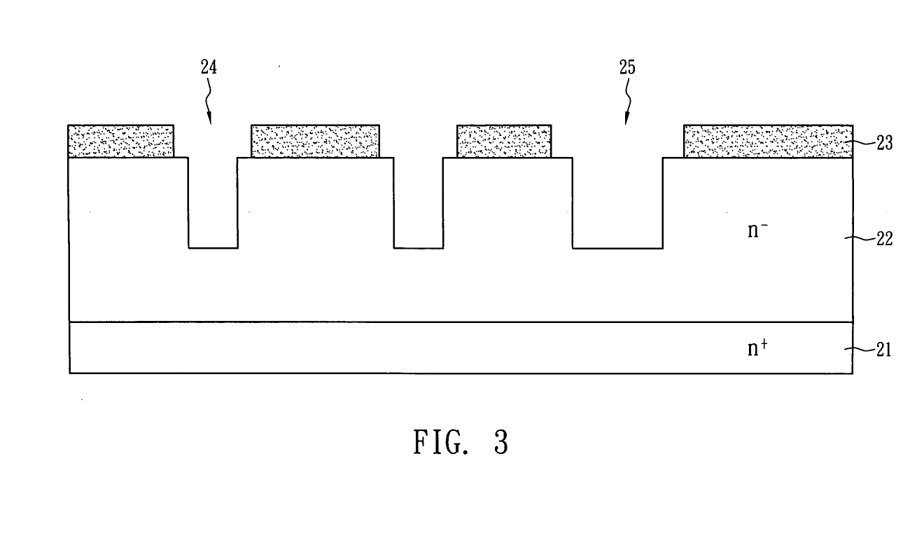

In FIG. 3, a lithography process is conducted to define the locations of trenches and an etching process is conducted afterwards to form trenches 24 and 25. The depths of the trenches 24 and 25 are between 1.2 and 1.4 μm. The trenches 24 on the left side will form transistor gates of cells. The trench 25 on the right side is at the peripheral of the die. Because the trench 25 will form a gate that is connected to a contact, the width of the trench 25 is greater than that of the trench 24.

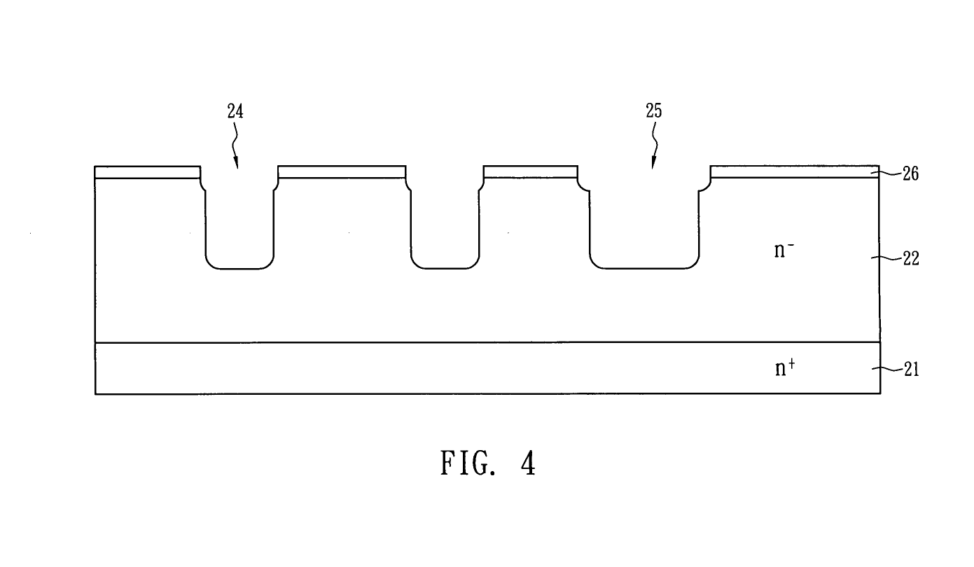

In FIG. 4, an oxidation process at 1150° C. is conducted, and a buffer hydrofluoric acid (BHF) is used to remove part of the oxidation layer 23. Then, an oxidation process is conducted to form a sacrificial oxide layer 26 of around 3500 angstroms.

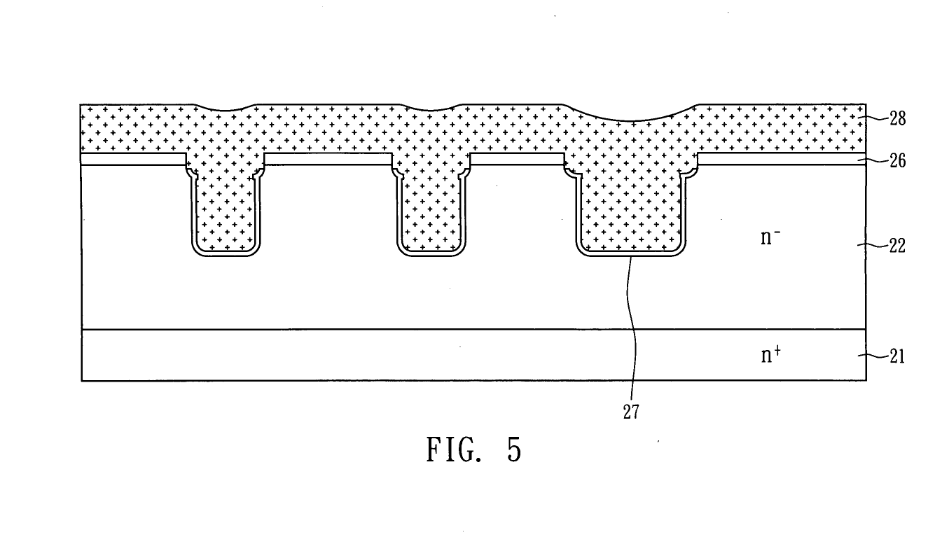

In FIG. 5, an oxidation process is conducted at 1000° C. so as to form a gate oxide layer 27 on the surfaces of the trenches 24 and 25, and the trenches 24 and 25 are filled with a doped polysilicon layer 28. In this embodiment, the thickness of the doped polysilicon layer 28 is around 8000 angstroms.

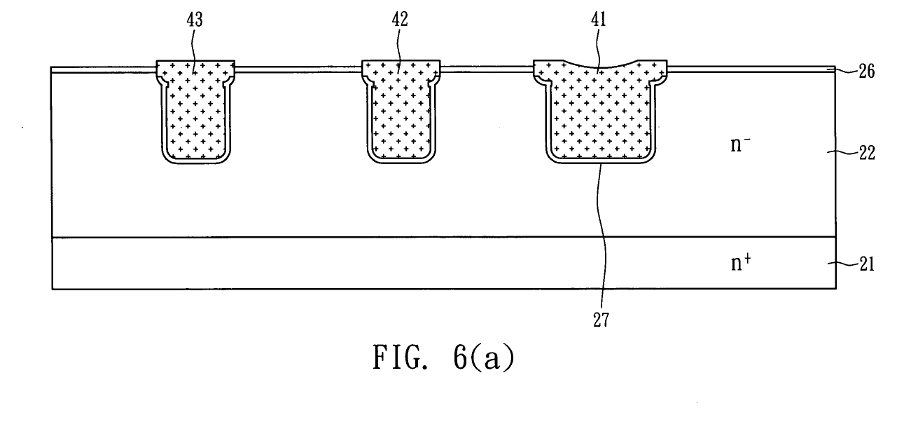

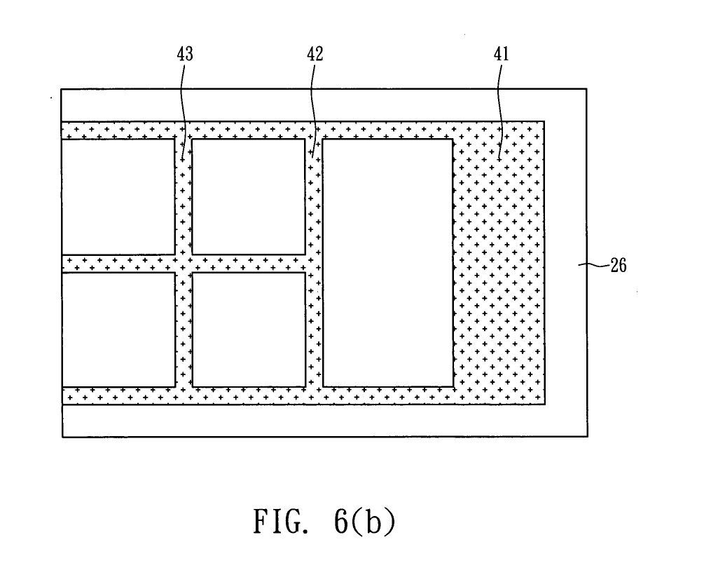

In FIG. 6(a), the doped polysilicon layer 28 is planarized to reach the sacrificial oxide 26 by chemical mechanical polishing or etching back, so as to form gates 41, 42 and 43. Then, the sacrificial oxide layer 26 is wet-etched to be of a thickness of 200 angstroms. FIG. 6(b) shows the top view of the structure of FIG. 6(a), wherein the gate 41 at the right side is electrically connected to the gates 42 and 43 of the cell area.

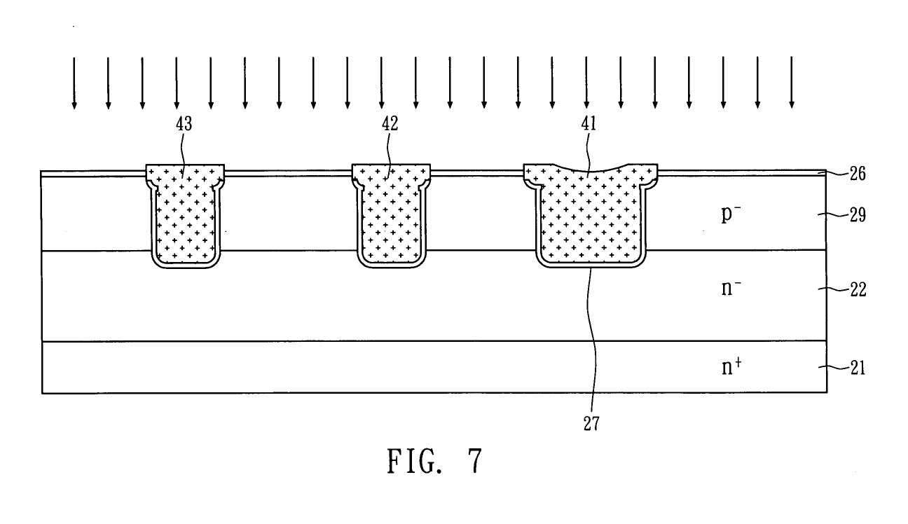

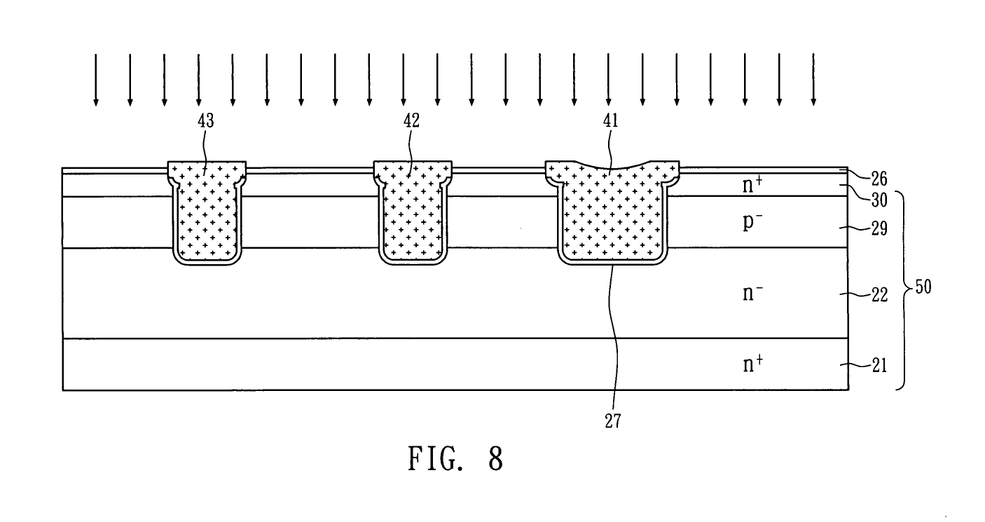

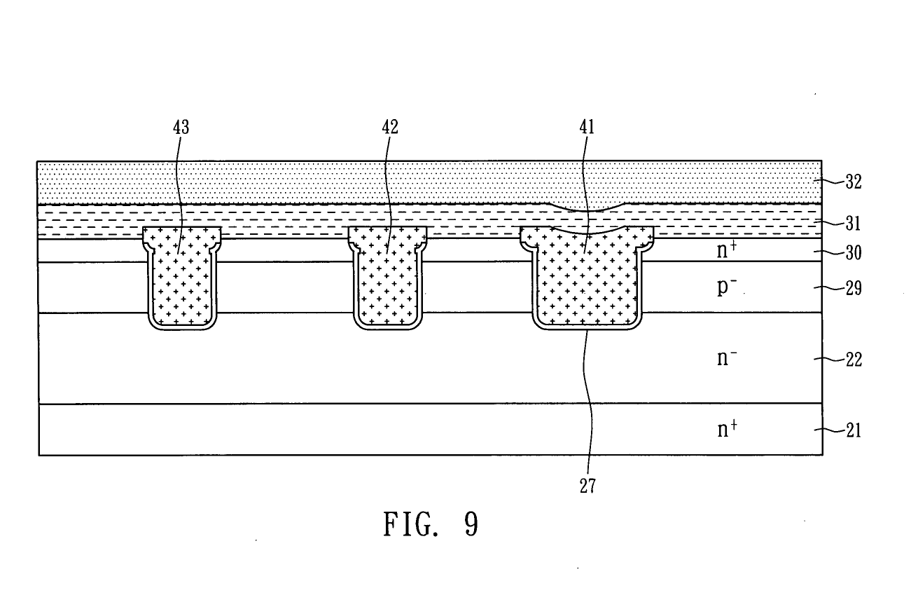

In FIG. 7, boron ions are implanted into the n⁻-type semiconductor layer 22 to form a p⁻-type semiconductor layer 29, followed by annealing at 1150° C. Arsenic ions are implanted into the p⁻-type semiconductor layer 29 with a dosage of 8E15 atom/cm², so as to form an n⁺-type semiconductor layer 30 as shown in FIG. 8. The semiconductor layers 21, 22, 29 and 30 form a semiconductor substrate 50, and the gates 41, 42 and 43 are formed in the semiconductor substrate 50. The n+ semiconductor layer 30 and the n⁻ semiconductor layer 22 serve as the source and the drain, respectively. The p⁻ semiconductor layer 29 serves as a channel region.

In FIG. 9, the sacrificial oxide layer 26 is removed, and a silicon-rich oxide layer 31 of a thickness around 2000 angstroms is formed by plasma enhanced chemical vapor deposition, and an oxide layer 32 of a thickness around 5300 angstroms serving as interlayer dielectric layer (ILD) is formed. In an embodiment, the oxide layer 32 comprises boro-phospho-silicate glass (BPSG).

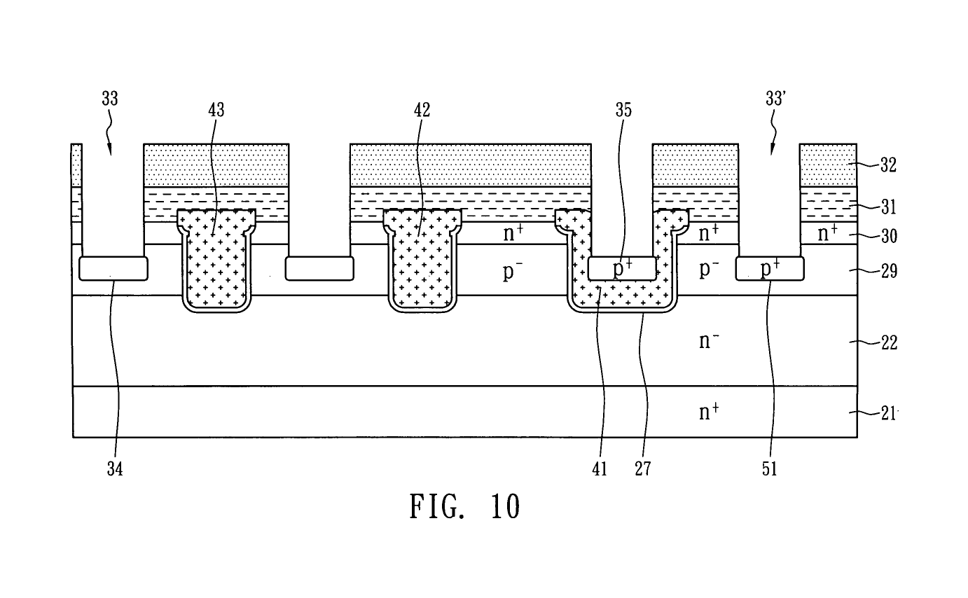

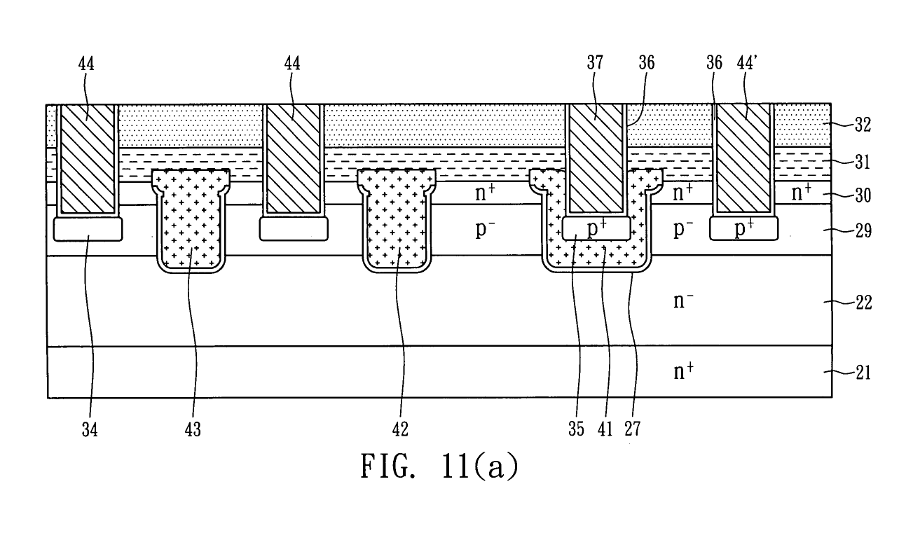

In FIG. 10, the n⁺ region 30 undergoes lithography and etching processes to form source openings 33 and a stripe opening 33′ for transistor base, and boron fluoride (BF2) implantation and annealing are performed to form p⁺ doping regions 34, 35 and 51. The doping regions 51 form a guard ring to stabilize the voltage p-substrate 29.

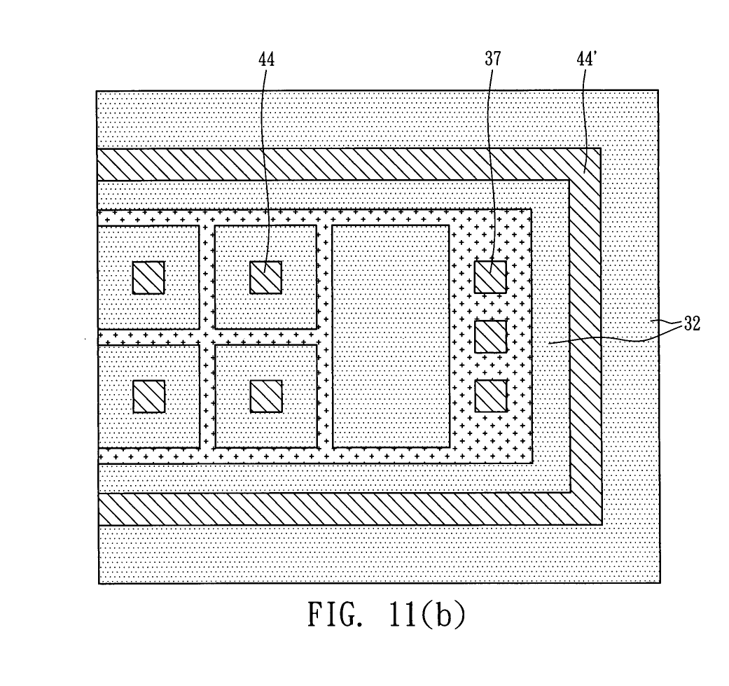

In FIGS. 11(a) and 11(b), where FIG. 11(b) is the top view of the structure of FIG. 11(a), titanium liner 36 is formed on the surfaces of the openings 33 and the stripe opening 33′ by sputtering and then annealing. Then, conductive connections are formed in the openings 33 and 33′. In this embodiment, the tungsten plugs 37 and 44 are formed in the opening 33, and the tungsten connection 44′ is formed in the stripe opening 33′. The tungsten plugs 37 and 44 and the tungsten connection 44′ are etched back to ensure that no tungsten metal remains. The tungsten plugs 37 are electrically connected to a bonding pad for transmitting gate control signals. The tungsten plugs 44 and the tungsten connection 44′ connected to p+ region 51 are electrically connected to a bonding pad for transmitting source control signals.

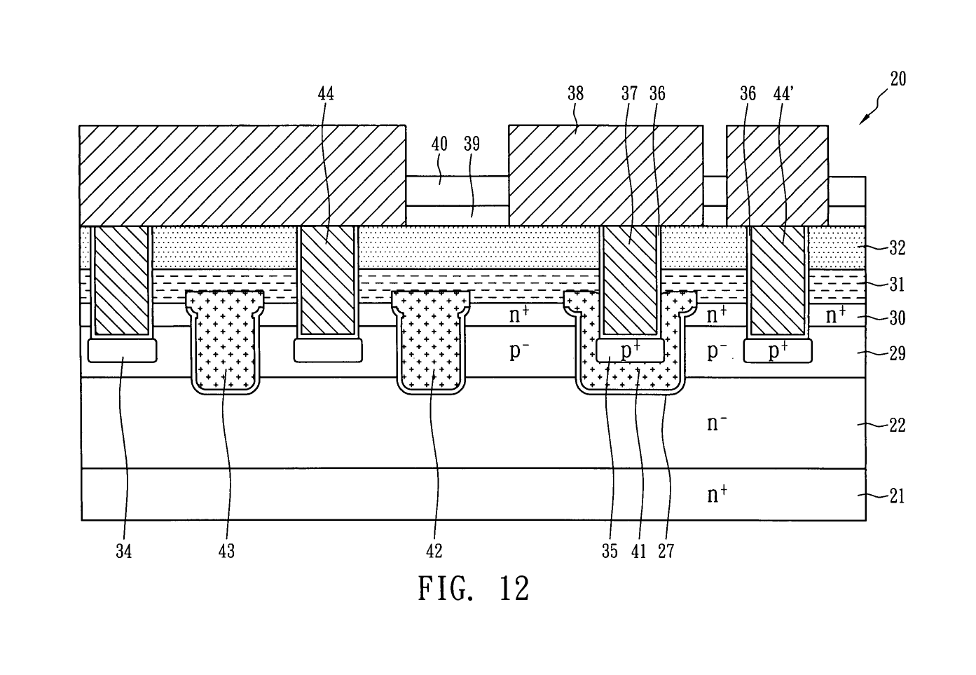

As shown in FIG. 12, an aluminum-copper metal layer 38 of a thickness around 30K to 40K angstroms is formed on the tungsten plugs 37 and the oxide layer 32 and is etched into a desired pattern. Afterwards, an oxide layer 39 and a nitride layer 40 are deposited between neighboring aluminum-copper metal layers 38 for isolation, and as a consequence the power MOSFET structure 20 of the present invention is formed.

In comparison with the power MOSFET shown in FIG. in which the gate at the peripheral is formed above the substrate, the gates 41, 42 and 43 of the present invention are formed in the semiconductor substrate at the same time, which makes it unnecessary to form a photo mask defining the gate 41, and a photo mask defining the isolation area for formation of the gate 41 connecting the contact is also not necessary. Moreover, when there is superior n⁻ substrate contact electricity at die peripheral, the peripheral should be of p-type and n-type implantation cannot be performed. Therefore, it is necessary to provide a cover for protection, and thus one more photo mask is needed. But as shown in FIG. 10, n⁺ regions 30 are removed and the contact windows are defined by the source contact window photo mask, so the n+ photo mask is not needed.

In accordance with the present invention, the number of photo masks can be decreased from 7 to 4; in other words, three photo masks can be spared, so the process can be significantly simplified and the cost is reduced.

The above-described embodiments of the present invention are intended to be illustrative only. Numerous alternative embodiments may be devised by those skilled in the art without departing from the scope of the following claims.

What is claimed is:

1. A power metal-oxide-semiconductor field effect transistor (MOSFET) structure, comprising:
at least one first gate placed in a cell area of a die and formed in a semiconductor substrate;
at least one second gate placed at the peripheral of the die and formed in the semiconductor substrate;
wherein the first and second gates are electrically connected, and the second gate are connected to a contact connecting to a first bonding pad to transmit gate control signals.

2. The power MOSFET structure in accordance with claim 1, further comprising a gate oxide layer between the first and second gates and the semiconductor substrate.

3. The power MOSFET structure in accordance with claim 1, wherein the contact is a tungsten plug.

4. The power MOSFET structure in accordance with claim 3, further comprising a titanium metal liner between the tungsten plug and the second gate.

5. The power MOSFET structure in accordance with claim 3, wherein the tungsten plug is connected to an aluminum-copper metal layer.

6. The power MOSFET structure in accordance with claim 3, wherein the bottom of the tungsten plug is connected to an ion implantation region.

7. The power MOSFET structure in accordance with claim 1, wherein the semiconductor substrate comprises from top to bottom a first semiconductor layer, a second semiconductor layer and a third semiconductor layer, the first and third semiconductor layers being of a first conductive type, the second semiconductor layer being of a second conductive type, and the first and third semiconductor layers serving respectively as a source and a drain of the power MOSFET.

8. The power MOSFET structure in accordance with claim 7, wherein the first semiconductor layer is electrically connected to a second bonding pad through a conductive connection for transmitting source control signals.

9. The power MOSFET structure in accordance with claim 8, wherein the conductive connection is a tungsten plug.

10. The power MOSFET structure in accordance with claim 9, wherein the bottom of the tungsten plug is connected to an ion implantation region.

11. The power MOSFET structure in accordance with claim 7, further comprising a guard ring formed in the second semiconductor layer, the guard ring being of the second conductive type, and the polarity of the guard ring being opposite to that of the second semiconductor layer.

12. The power MOSFET structure in accordance with claim 11, wherein the guard ring is electrically connected to a second bonding pad through a metal connection for transmitting source control signals.

13. A method for manufacturing a power MOSFET, comprising:
forming at least one first trench and at least one second trench in a semiconductor substrate, wherein the first trench is in a cell area of a die and the second trench is at the peripheral of the die;
filling a conductive layer in the first trench and the second trench to form a first gate and a second gate, wherein the first and second gates are electrically connected;
forming a dielectric layer on the first and second gates and the semiconductor substrate; and
forming a contact penetrating through the dielectric layer to the second gate, the contact being electrically connected to a first bonding pad for transmitting gate control signals.

14. The method in accordance with claim 13, wherein the width of the second trench is greater than that of the first trench.

15. The method in accordance with claim 13, wherein the depths of the first trench and the second trench are between 1.2 and 1.4 μm.

16. The method in accordance with claim 13, wherein the first gate and the second gate are formed by filling a polysilicon layer and then planarization.

17. The method in accordance with claim 16, wherein the planarization performs chemical mechanical polishing.

18. The method in accordance with claim 13, wherein the semiconductor substrate comprises from top to bottom a first semiconductor layer, a second semiconductor layer and a third semiconductor layer, the first and third semiconductor layers being of a first conductive type, the second semiconductor layer being of a second conductive type, and the first and third semiconductor layers respectively serve as the source and the drain of the power MOSFET.

19. The method in accordance with claim 18, wherein a conductive connection connected to the first semiconductor layer is formed at the same time when the contact is formed, and the conductive connection is electrically connected to a second bonding pad for transmitting source control signals.

20. The method in accordance with claim 13, wherein forming the dielectric layer comprises the steps of forming a silicon-rich oxide layer and an oxidation layer in sequence.

21. The method in accordance with claim 13, further comprising a step of forming an aluminum-copper metal layer connecting to the top of the contact.

22. The method in accordance with claim 18, wherein a metal connection connected to a guard ring of the second semiconductor layer is formed at the same time when the contact is formed, the guard ring being of a second conductive type, and the polarity of the guard ring being opposite to that of the second conductive layer.

23. The method in accordance with claim 22, wherein the guard ring is electrically connected to a second bonding pad for transmitting source control signals.
